(19) United States
(12) Patent Application Publication
(10) Pub. No.: US 2026/0068052 A1
(43) Pub. Date: Mar. 5, 2026

(54) ELECTRONIC DEVICE

(71) Applicant: Samsung Display Co., Ltd., Yongin-si (KR)

(72) Inventors: DAE-SIK LEE, Yongin-si (KR); MIN-SOO CHOI, Yongin-si (KR); SEUNGHO PARK, Yongin-si (KR); JONGMIN SHIM, Yongin-si (KR)

(21) Appl. No.: 19/240,556

(22) Filed: Jun. 17, 2025

(30) Foreign Application Priority Data
Sep. 5, 2024 (KR) 10-2024-0120641

(51) Int. Cl. H05K 1/14; H05K 1/02; H05K 1/11; H10K 59/95

(52) U.S. Cl. CPC H05K 1/147; H05K 1/0268; H05K 1/117; H10K 59/95

(57) ABSTRACT

An electronic device includes a display panel, a first printed circuit board arranged in a second direction with the display panel, and electrically connected to the display panel, a second printed circuit board adjacent to a first side of the first printed circuit board opposed to a second side thereof adjacent to the display panel in the second direction, and a connection part including a connection cable connecting the first printed circuit board and the second printed circuit board. The first printed circuit board includes a substrate, and terminals disposed on the substrate to be electrically connected to the connection part and the display panel, and including signal pins, power pins, and test pins arranged in a first direction crossing the second direction. A width of the test pin is greater than that of the signal pin, and smaller than that of the power pin in the first direction.

This application claims priority to Korean Patent Application No. 10-2024-0120641, filed on Sep. 5, 2024, and all the benefits accruing therefrom under 35 U.S.C. § 119, the content of which in its entirety is herein incorporated by reference.

### BACKGROUND

The present disclosure herein relates to an electronic device.

Various electronic devices used in a multimedia device such as a television, a mobile phone, a tablet computer, a navigation system, a game console are being developed.

As the application fields of such electronic devices diversify, types of display panel for displaying an image displayed on the electronic devices are also diversifying.

Recently, a display panel may include a light-emitting display panel, and the light-emitting display panel may include an organic light-emitting display panel, inorganic light-emitting display panel, or a quantum dot light-emitting display panel and the like.

### SUMMARY

The present disclosure provides an electronic device with an improved reliability of sensing incorrect fastening.

An embodiment of the invention provides an electronic device including a display panel of which a major surface is parallel to a plane defined by a first direction and a second direction crossing the first direction, a first printed circuit board arranged in the second direction with the display panel, and electrically connected to the display panel, a second printed circuit board disposed adjacent to a first side of the first printed circuit board opposed to a second side of the first printed circuit board adjacent to the display panel in the second direction, and a connection part including a connection cable connecting the first printed circuit board and the second printed circuit board, where the first printed circuit board includes a first substrate, and a plurality of terminals disposed on the first substrate to be electrically connected to the connection part and the display panel, and including signal pins, power pins, and test pins arranged in the first direction, and a width of the test pin in the first direction is greater than a width of the signal pin in the first direction, and smaller than a width of the power pin in the first direction.

In an embodiment of the invention, an electronic device includes a display module, and a window disposed on the display module, wherein the display module includes a display panel including a plurality of pixels which display an image, a first printed circuit board adjacent to one side of the display panel, and including a plurality of terminals electrically connected to the display panel, a second printed circuit board adjacent to a first side of the first printed circuit board spaced apart from the display panel, and a connection part including a connection cable connecting the first printed circuit board and the second printed circuit board, where the terminals include a plurality of signal pins, a plurality of power pins, and a plurality of test pins arranged in a first direction, and a width of the signal pins in the first direction, a width of the power pins in the first direction, and a width of the test pins in the first direction are different from each other.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of an electronic device according to an embodiment of the invention;

FIG. 2 is an exploded perspective view of the electronic device illustrated in FIG. 1;

FIG. 3 is a plan view of a display module illustrated in FIG. 2;

FIG. 4A is a perspective view of a first connector and printed wirings illustrated in FIG. 3;

FIG. 4B is a cross-sectional view of the first connector taken along line I-I′ illustrated in FIG. 4A;

FIG. 5 is a perspective view illustrating a terminal illustrated in FIG. 4B;

FIGS. 6A and 6B are perspective views illustrating a connection between a connection part and a first connector;

FIG. 7 is a cross-sectional view of the connection part and the first connector taken along line II-II′ illustrated in FIG. 6B;

FIG. 8 is a plan view illustrating a connection between protrusion pins and test pins; and

FIG. 9 is a graph shown to describe a protrusion amount of test pins according to an embodiment of the invention and a protrusion amount of test pins according to Comparative Example.

### DETAILED DESCRIPTION

In this specification, it will be understood that when an element (or a region, a layer, a portion, or the like) is referred to as being “on”, “connected to” or “coupled to” another element, it can be directly disposed on/connected to/coupled to the other element or layer or intervening elements may be disposed therebetween.

Like numerals or symbols refer to like elements throughout. Also, in the drawings, the thicknesses, ratios, and dimensions of the elements are exaggerated for effective description of the technical contents. The term “and/or” includes all of one or more combinations which can be defined by related elements.

Although the terms “first”, “second”, etc. may be used to describe various elements, these elements should not be limited by these terms. These terms are only used to distinguish one element from another element. For example, a first element may be referred to as a second element, and similarly, a second element may also be referred to as a first element without departing from the scope of the present disclosure. The singular forms include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Unless otherwise defined, all terms (including technical and scientific terms) used herein have the same meaning as commonly understood by one of ordinary skills in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, embodiments of the invention will be described with reference to the accompanying drawings.

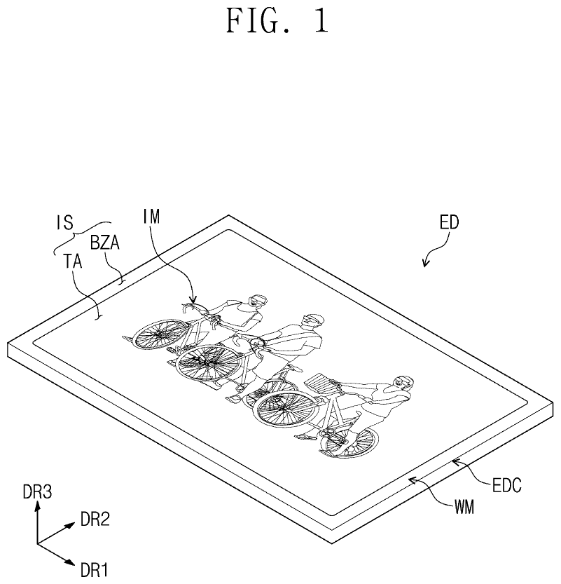

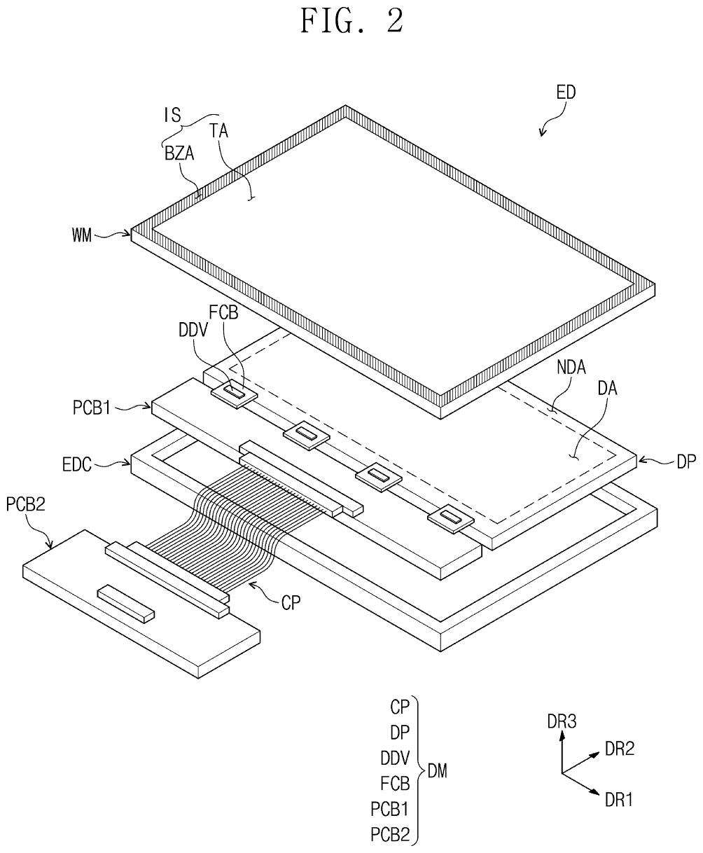

FIG. 1 is a perspective view of an electronic device according to an embodiment of the invention. FIG. 2 is an exploded perspective view of the electronic device illustrated in FIG. 1.

Referring to FIG. 1, an electronic device ED may be a device activated in response to an electrical signal. The electronic device ED according to the invention may be a small- or medium-sized electronic device such as a mobile phone, a tablet computer, a car navigation system, a game console, as well as an electronic device such as a television and a monitor. These are provided only as examples, and the electronic device ED may also be applied to other electronic apparatuses without departing from the invention. Although the electronic device ED having a television shape is illustrated in FIG. 1, an embodiment of the invention is not limited thereto.

The electronic device ED may have a rectangular shape having long sides extending in a first direction DR1 and short sides extending in a second direction DR2 crossing the first direction DR1. However, a shape of the electronic device ED is not limited thereto, and the electronic device ED may be provided in various shapes.

Hereinafter, a direction crossing substantially perpendicularly to a plane defined by the first direction DR1 and the second direction DR2, may be defined as a third direction DR3. In this specification, the wording “in a plan view” may indicate a state seen from the third direction DR3 (i.e., thickness direction of the electronic device ED). In this specification, the wording “on a cross section” may be defined as a state seen from the first direction DR1 or the second direction DR2.

The electronic device ED may sense an external input applied from the outside. The external input may include various forms of inputs provided from the outside of the electronic device ED. The electronic device ED according to an embodiment of the invention may sense a user's external input applied from the outside. The user's external input may be one of various types of external inputs such as a part of the user's body, light, heat, and pressure or combinations thereof. Also, the electronic device ED may sense the user's external input applied to a side surface or a rear surface of the electronic device ED depending on a structure of the electronic device ED, but is not limited to any one embodiment.

The electronic device ED according to an embodiment of the invention may sense inputs provided by an input device (for example, a stylus pen, an active pen, a touch pen, an electronic pen and the like) in addition to the user's external input.

A front surface of the electronic device ED may be divided into a transmission region TA and a bezel region BZA. The transmission region TA may be a region in which an image IM is displayed. The user may view the image IM through the transmission region TA. In this embodiment, the transmission region TA is illustrated as a square shape with rounded corners. However, this is illustrated as an example, and the transmission region TA may have various shapes and is not limited to any one embodiment.

The bezel region BZA is adjacent to the transmission region TA. The bezel region BZA may have a predetermined color. The bezel region BZA may surround the transmission region TA. Thus, the shape of the transmission region TA may substantially be defined by the bezel region BZA. However, this is illustrated as an example, and the bezel region BZA may be disposed adjacent to only one side of the transmission region TA, or may be omitted. The electronic device ED according to an embodiment of the invention may include various embodiments, and is not limited to any one embodiment.

Referring to FIGS. 1 and 2, the electronic device ED may include a window WM, a display module DM, and an exterior case EDC.

The window WM may be made of a transparent material that allows the image IM to be output. For example, the window WM may be made of glass, sapphire, or plastic and the like. The window WM is illustrated as a single layer, but is not limited thereto and may include a plurality of layers.

Meanwhile, although not illustrated, the bezel region BZA of the electronic device ED described above may substantially be provided as a region in which a material having a predetermined color is printed onto one region of the window WM. As an example of the invention, the window WM may include a light blocking pattern for defining the bezel region BZA. The light blocking pattern may be a colored organic film and be formed, for example, by a coating method.

The window WM may be coupled to the display module DM through an adhesive film. As an example of the invention, the adhesive film may include an optically clear adhesive film (OCA). However, the adhesive film is not limited thereto, and may include a typical adhesive or bonding agent. For example, the adhesive film may include an optically clear resin (OCR) or a pressure sensitive adhesive film (PSA).

An anti-reflection layer may be further disposed between the window WM and the display module DM. The anti-reflection layer reduces a reflectance for an external light incident from above the window WM. The anti-reflection layer according to an embodiment of the invention may include a retarder and a polarizer. The retarder may be a film type or a liquid crystal coating type, and may include a λ/2 retarder and/or a λ/4 retarder. The polarizer also may be a film type or a liquid crystal coating type. The film type may include a stretchable synthetic resin film, and the liquid crystal coating type may include liquid crystals arranged in a predetermined arrangement. The retarder and the polarizer may be configured by a single polarization film.

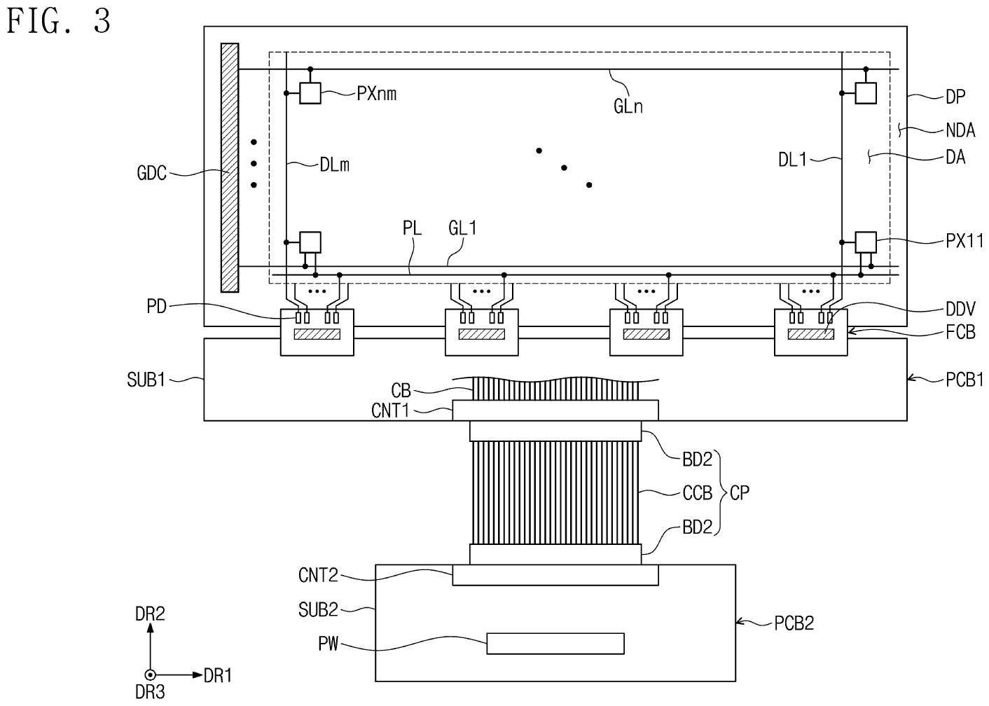

As an example of the invention, the anti-reflection layer may include color filters. An arrangement of the color filters may be determined by considering the colors of light generated by a plurality of pixels PX11-PXnm (see FIG. 3) included in a display panel DP to be described later. The anti-reflection layer may further include a light blocking pattern.

The display module DM may include the display panel DP, a first printed circuit board PCB1, a second printed circuit board PCB2, a plurality of flexible circuit boards FCB, a connection part CP, and a plurality of data driving parts DDV.

The display panel DP may include a display region DA for displaying the image IM and a non-display region NDA adjacent to the display region DA. The display region DA may be a region in which the image IM provided by the display panel DP is output. The non-display region NDA may surround the display region DA. However, this is illustrated as an example, and the non-display region NDA may be defined in various shapes and is not limited to any one embodiment. For example, the non-display region NDA may be provided adjacent to one side or both sides of the display region DA. According to an embodiment, the display region DA of the display panel DP may correspond to at least a portion of the transmission region TA, and the non-display region NDA may correspond to the bezel region BZA.

The display panel DP according to an embodiment of the invention may be a light-emitting display panel. As an example, the display panel DP may be an organic light-emitting display panel, an inorganic light-emitting display panel or a quantum dot light-emitting display panel. A light-emitting layer of the organic light-emitting display panel may include an organic light-emitting material. A light-emitting layer of the inorganic light-emitting display panel may include an inorganic light-emitting material. A light-emitting layer of the quantum dot display panel may include quantum dots, quantum rods, and the like. Hereinafter, the display panel DP is described as an organic light-emitting display panel in this embodiment.

As an example of the invention, the electronic device ED may further include an input sensing layer for sensing an external input (for example, a touch event and the like). The input sensing layer may be disposed directly on the display panel DP. According to an embodiment of the invention, the input sensing layer may be formed on the display panel DP through a continuous process. That is, when the input sensing layer is disposed directly on the display panel DP, an adhesive film may not be disposed between the input sensing layer and the display panel DP. However, an embodiment of the invention is not limited thereto. The adhesive film may be disposed between the input sensing layer and the display panel DP. In this case, the input sensing layer is not produced together with the display panel DP through the continuous process, but produced through a separate process from the display panel DP, and then the input sensing layer may be fixed to a top surface of the display panel DP by the adhesive film.

The first printed circuit board PCB1 may be disposed adjacent to one long side among long sides of the display panel DP. The first printed circuit board PCB1 may have a rectangular shape having long sides extending in the first direction DR1 and having short sides extending in the second direction DR2. However, a shape of the first printed circuit board PCB1 is not limited thereto.

The flexible circuit boards FCB may be arranged in the first direction DR1. The flexible circuit boards FCB may be disposed between the display panel DP and the first printed circuit board PCB1. One side of two sides of each of the flexible circuit boards FCB opposed to each other in the second direction DR2 may be connected to the display panel DP, and the other side may be connected to the first printed circuit board PCB1. Thus, the first printed circuit board PCB1 may be electrically connected to the display panel DP.

The data driving parts DDV may be disposed on the flexible circuit boards FCB. The data driving parts DDV may be mounted on the flexible circuit boards FCB. The data driving parts DDV will be described in detail in FIG. 3.

The second printed circuit board PCB2 may be disposed to face one side of two sides of the first printed circuit board PCB1 opposed to each other in the second direction DR2. The display panel DP, the first printed circuit board PCB1, and the second printed circuit board PCB2 may be arranged in the second direction DR2. One side of the two sides of the first printed circuit board PCB1 opposed to each other in the second direction DR2 may be defined as a side opposite to the other side facing the display panel DP.

The connection part CP may be disposed between the first printed circuit board PCB1 and the second printed circuit board PCB2. The connection part CP may electrically connect the first printed circuit board PCB1 and the second printed circuit board PCB2 to each other. The second printed circuit board PCB2 may be electrically connected to the display panel DP by the connection part CP, the first printed circuit board PCB1, and the flexible circuit boards FCB. Thus, a signal provided from the second printed circuit board PCB2 may be transferred to the display panel DP. A connection between the first printed circuit board PCB1, the second printed circuit board PCB2, the flexible circuit board FCB, and the display panel DP will be described in detail hereinafter.

The exterior case EDC may be coupled to the window WM and define the exterior of the electronic device ED. The exterior case EDC may absorb an impact applied from the outside and prevent foreign matter/moisture, etc. from infiltrating into the display panel DP and thereby protect the components contained in the exterior case EDC. Meanwhile, as an example of the invention, the exterior case EDC may be provided in a form in which a plurality of storage members are coupled. The electronic device ED according to an embodiment of the invention

may further include an electronic module including various functional modules for operating the display panel DP, a power supply module for supplying power required for overall operation of the electronic device ED, a bracket coupled with the exterior case EDC to divide the internal space of the electronic device ED.

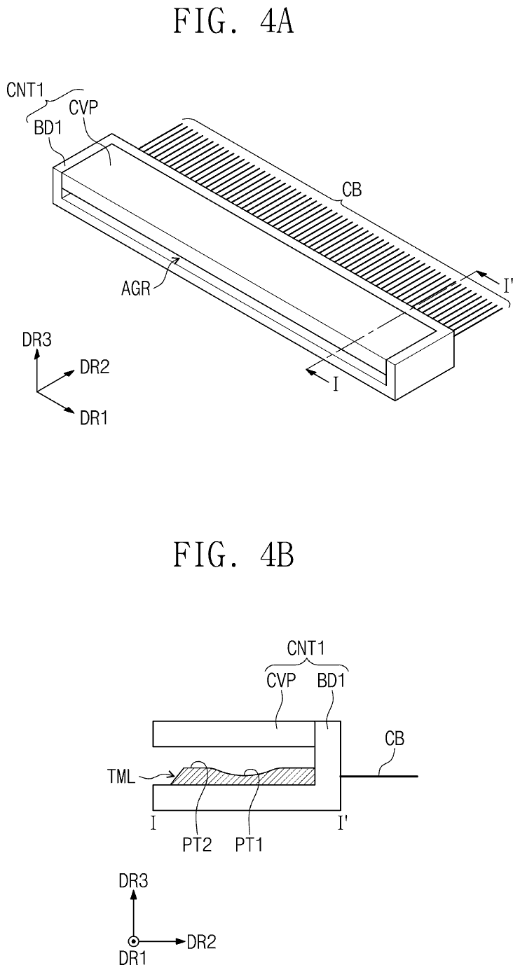

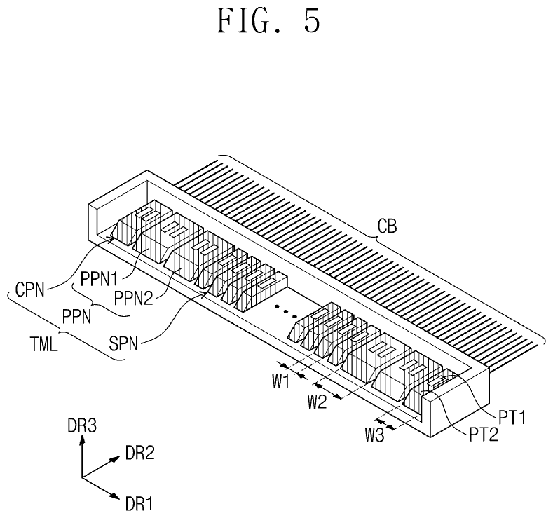

FIG. 3 is a plan view of a display module illustrated in FIG. 2. FIG. 4A is a perspective view of a first connector and printed wirings illustrated in FIG. 3. FIG. 4B is a cross-sectional view of the first connector taken along line I-I′ illustrated in FIG. 4A. FIG. 5 is a perspective view illustrating a terminal illustrated in FIG. 4B.

For the convenience of explanation, a first substrate SUB1 is omitted in FIGS. 4A to 5, and a cover part CVP is omitted in FIG. 5.

Among components illustrated in FIGS. 3 to 5, the descriptions of the components that are the same as the components explained with reference to the drawings will be omitted or explained briefly.

Referring to FIG. 3, the display panel DP may include a plurality of pads PD, a plurality of signal lines GL1-GLn and DL1-DLm, a power line PL, and pixels PX11-PXnm. The plurality of the signal lines GL1-GLn and DL1-DLm may include a plurality of gate lines GL1-GLn and a plurality of data lines DL1-DLm.

The display panel DP may include a display region DA and a non-display region NDA. The display region DA and the non-display region NDA may be distinguished from each other depending on whether the plurality of the pixels PX11-PXnm are disposed. The plurality of the pixels PX11-PXnm may be disposed in the display region DA and may not be disposed in the non-display region NDA.

The plurality of the pixels PX11-PXnm may each be connected to a corresponding gate line among the plurality of the gate lines GL1-GLn, and to a corresponding data line among the plurality of the data lines DL1-DLm. The plurality of the pixels PX11-PXnm may each be electrically connected to the power line PL. The plurality of the pixels PX11-PXnm may each include a pixel driving circuit and a display element. More types of signal lines may be provided on the display panel DP according to the configuration of the pixel driving circuit of the plurality of the pixels PX11-PXnm.

The display module DM may further include a scan driving circuit GDC. The scan driving circuit GDC and the plurality of pads PD may be disposed in the non-display region NDA. The scan driving circuit GDC and the circuits in the display panel DP may be formed through the same process. Some of the plurality of the pads PD may be electrically connected to the plurality of the data lines DL1-DLm. Some of the plurality of the pads PD may be electrically connected to the power line PL.

Flexible circuit boards FCB may be disposed on one side of two sides of the display panel DP opposed to each other in the second direction DR2. The flexible circuit boards FCB may be arranged in the first direction DR1 along the long sides of the display panel DP. The flexible circuit boards FCB may be connected to the pads PD. The flexible circuit boards FCB may provide the display panel DP with electrical signals for driving the display panel DP. The flexible circuit boards FCB may be electrically connected to the display panel DP through the pads PD.

The data driving parts DDV may be mounted on the flexible circuit boards FCB. For example, the data driving parts DDV may be mounted on the flexible circuit boards FCB in a chip-on-film (COF) manner. The data driving parts DDV may be a driving chip which transfers an electrical signal to the display panel DP. The data driving circuit may be a part of the circuit formed in the data driving parts DDV. The data driving parts DDV may be electrically connected to the pixels PX11-PXnm through the pads PD disposed in the non-display region NDA.

The first printed circuit board PCB1 may be connected to the flexible circuit boards FCB. The first printed circuit board PCB1 and the flexible circuit boards FCB may be electrically connected to each other. The first printed circuit board PCB1 may transfer, to the flexible circuit boards FCB, the signals transferred from the second printed circuit board PCB2.

Referring to FIGS. 3, 4A, and 4B, the first printed circuit board PCB1 may include a first substrate SUB1, a first connector CNT1, a plurality of terminals TML, and a plurality of printed wirings CB. A major surface of the first substrate SUB1 may be parallel to a plane defined by the first direction DR1 and the second direction DR2. The first substrate SUB1 may extend longer in the first direction DR1 than in the second direction DR2.

The printed wirings CB may be disposed on the first substrate SUB1. One end of each of the printed wirings CB may be connected to the flexible circuit board FCB, and the other end may be connected to the first connector CNT1.

The first connector CNT1 may be disposed adjacent to one side of two sides of the first substrate SUB1 opposed to each other in the second direction DR2. The one side of the two sides of the first substrate SUB1 opposed to each other in the second direction DR2 may be defined as a side spaced apart from the display panel DP.

The first connector CNT1 may include a first body part BD1 and a cover part CVP. The first body part BD1 may have a partial shape of a cuboid. In a plan view, the first body part BD1 may extend longer in the first direction DR1 than in the second direction DR2. A fastening groove AGR may be defined in an upper surface of the first body part BD1. The fastening groove AGR may have a shape corresponding to a part of a cuboid.

The terminal TML may be disposed inside the fastening groove AGR. The terminal TML may be disposed on the inside of the first body part BD1 defining the fastening groove AGR. The terminal TML may be electrically connected to the printed wirings CB. Although not illustrated, the terminal TML and the printed wirings CB may be electrically connected to each other inside the first body part BD1. The terminal TML may be electrically connected to the flexible circuit boards FCB and the display panel DP through the printed wirings CB.

An upper surface of the terminal TML may be recessed. The highest part of the upper surface of the terminal TML may be defined as a second part PT2, and the other part of the upper surface of the terminal TML recessed in a direction opposite to the third direction DR3 from the second part PT2 may be defined as a first part PT1. The height of the first part PT1 may be lower than the height of the second part PT2.

Referring to FIG. 5, the terminal TML may include a plurality of signal pins SPN, a plurality of power pins PPN, and a plurality of test pins CPN. The signal pins SPN, the power pins PPN, and the test pins CPN may be arranged in the first direction DR1.

Specifically, the signal pins SPN may be arranged in the middle of the fastening groove AGR. The power pins PPN may be disposed on respective sides of the signal pins SPN opposed to each other in the first direction DR1. The signal pins SPN may be disposed between the power pins PPN.

The test pins CPN may be disposed outside the power pins PPN. The power pins PPN and the signal pins SPN may be disposed between the test pins CPN spaced apart from each other in the first direction DR1.

The test pins CPN are disposed on the outmost sides in the first direction DR1 because normal connection of the test pins CPN and protrusion pins PTN to be described later indicates that the signal pins SPN and the protrusion pins PTN, and the power pins PPN and the protrusion pins PTN are connected normally.

A pair of power pins PPN adjacent to each other in the first direction DR1 may include first power pins PPN1 and second power pins PPN2. The first power pins PPN1 may be disposed farther from the signal pins SPN than the second power pins PPN2.

The first power pins PPN1 may provide power to the display panel DP. The power may be provided to the power line PL. The second power pins PPN2 may provide common power to the display panel DP. The common power may have a lower voltage level than the power.

The signal pins SPN may transfer to the display panel DP an electrical signal transferred from the second printed circuit board PCB2. The electrical signal may be a signal for driving the display panel DP. The electrical signal may have a lower voltage level than the power and the common power.

The test pins CPN may sense an incorrect fastening between a connection cable CCB and the signal pins SPN, and the connection cable CCB and the power pins PPN. The sensing of the incorrect fastening of the test pins CPN will be described in detail later.

A width of each of the signal pins SPN in the first direction DR1 may be defined as a first width W1. A width of each of the power pins PPN in the first direction DR1 may be defined as a second width W2. A width of each of the test pins CPN in the first direction DR1 may be defined as a third width W3.

The second width W2 may be greater than the first width W1. The power pins PPN may have a greater area than the signal pins SPN. This makes it possible for the power pins PPN to transfer with ease to the display panel DP the power and the common power with high voltage. Thus, the reliability of the electronic device ED (see FIG. 1) may be improved.

The third width W3 may be greater than the first width W1. The third width W3 may be smaller than the second width W2. The test pins CPN may have a greater area than the signal pins SPN. Thus, the test pins CPN may be greater in rigidity than the signal pins SPN.

The cover part CVP may be disposed on the terminal TML. In a plan view, the cover part CVP may cover the terminal TML.

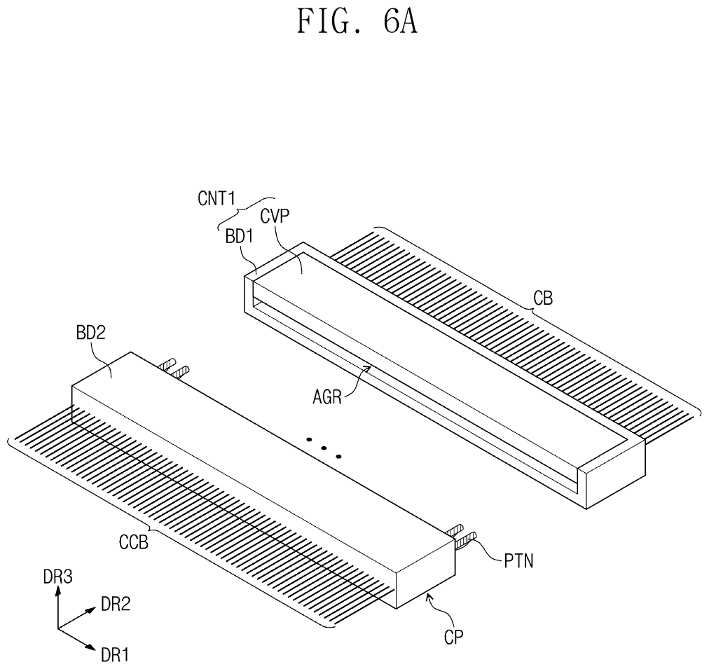

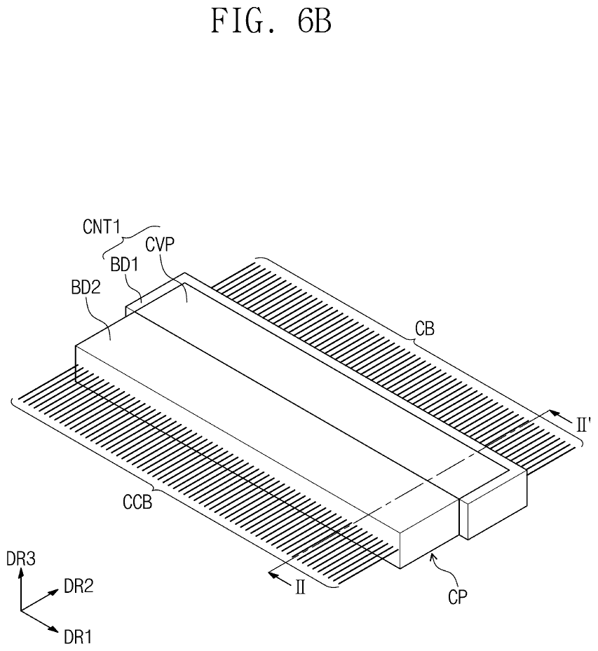

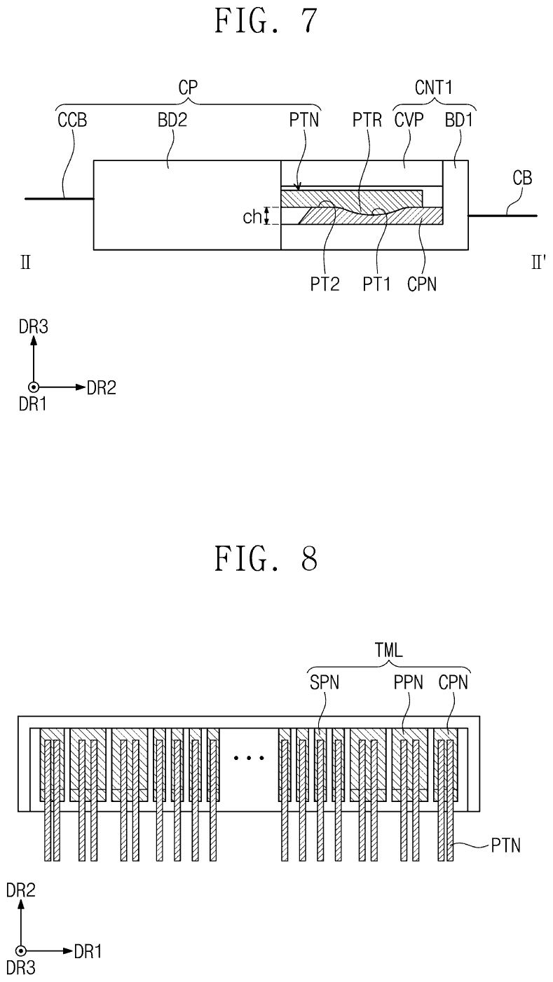

FIGS. 6A and 6B are perspective views illustrating a connection between a connection part and a first connector. FIG. 7 is a cross-sectional view of the connection part and the first connector taken along line II-II′ illustrated in FIG. 6B. FIG. 8 is a plan view illustrating a connection between protrusion pins and test pins.

As an example, in FIGS. 6A to 7, only one of second body parts BD2 among a plurality of the second body parts BD2 is illustrated, but the other one of the second body parts BD2 may also have the substantially same structure.

For the convenience of explanation, the cover part CVP is omitted in FIG. 8.

Among components illustrated in FIGS. 6A to 8, the descriptions of the components that are the same as the components explained with reference to the drawings will be omitted or explained briefly.

Referring to FIGS. 3 and 6A, the connection part CP may be disposed between the first printed circuit board PCB1 and the second printed circuit board PCB2.

The connection part CP may include the connection cable CCB, a plurality of the protrusion pins PTN, and a plurality of the second body parts BD2. The connection cable CCB may be disposed between the first printed circuit board PCB1 and the second printed circuit board PCB2. The connection cable CCB may be a flexible flat cable (FFC). The flexible flat cable may include a plurality of core wires made of conductors such as copper.

The second body parts BD2 may be connected to both ends of the connection cable CCB opposed to each other in the second direction DR2. The second body parts BD2 may have a cuboidal shape, but the shape of the second body parts BD2 is not limited thereto.

The protrusion pins PTN may be disposed on one side of two sides of the second body parts BD2 opposed to each other in the second direction DR2. The one side of the two sides of the second body parts BD2 opposed to each other in the second direction DR2 may be defined as a side opposite to the other side facing the one side. The protrusion pins PTN may be arranged in the second direction DR2 on the one side of the second body parts BD2. Although not illustrated, the protrusion pins PTN and the connection cable CCB may be electrically connected to each other inside the second body parts BD2.

Referring to FIGS. 6B and 7, the connection part CP may be connected to the first printed circuit board PCB1. The connection part CP may be electrically connected to the first printed circuit board PCB1. The second body part BD2 may be adjacent to one side of the first body part BD1 having the fastening groove AGR defined therein.

The protrusion pins PTN may be disposed inside the fastening groove AGR. Inside the fastening groove AGR, the protrusion pins PTN and the test pins CPN may be in contact with each other. The bottom surface of each of the protrusion pins PTN may include a protrusion PTR further protruding toward the bottom (i.e., direction opposite to the third direction DR3) than the surroundings. The protrusion PTR may be disposed on a recessed space defined by the first part PT1 and be in contact with the test pins CPN.

When the connection part CP and the first connector CNT1 are connected, pressure may be applied to a portion of the cover part CVP overlapping the test pins CPN so that the protrusion pins PTN (see FIG. 7) may be in contact with the test pins CPN. When each of the test pins CPN and each of the signal pins SPN have the same width, the rigidity of the test pins CPN may be decreased. Due to the pressure, the test pins CPN may be deformed. Thus, the test pins CPN and the protrusion pins PTN (see FIG. 7) may not be in contact with each other, and the reliability of sensing incorrect fastening between the connection part CP and the first connector CNT1 may be reduced.

According to an embodiment of the invention, the width of each of the test pins CPN in the first direction DR1 may increase, and the rigidity of the test pins CPN may be increased thereby. Thus, even when the pressure is applied, the test pins CPN may not be deformed.

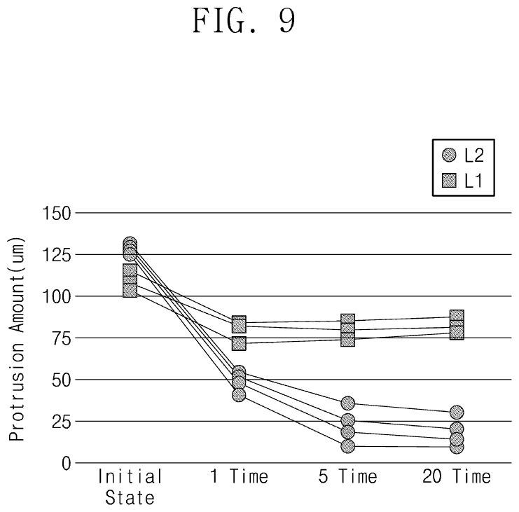

FIG. 9 is a graph shown to describe a protrusion amount of test pins according to an embodiment of the invention and a protrusion amount of test pins according to Comparative Example.

Referring to FIGS. 7 and 9, the X axis of the graph in FIG. 9 represents the number of times pressure is applied to the test pins CPN. The Y axis of the graph represents the protrusion amount of the test pins CPN. The protrusion amount (ch) of the test pins CPN may be defined as a length from the upper surface of the first body part BD1 under the test pin CPN to the second part PT2. That is, the protrusion amount (ch) is a thickness of the test pin CPN in the third direction DR3 in the second part PT2. A first graph L1 shows the protrusion amount (ch) versus the number of times pressure is applied when each of the test pins CPN and each of the signal pins SPN have the same width in the first direction DR1. That is, the first graph L1 is a graph when each of the test pins CPN has the first width W1. A second graph L2 shows the protrusion amount (ch) versus the number of times pressure is applied when each of the test pins CPN has the third width W3 greater than the first width W1.

When each of the test pins CPN has the first width W1, the test pins CPN may be buckled due to pressure on the inner surfaces of the first body part BD1 defining the fastening groove AGR. As can be seen through the first graph L1, the protrusion amount (ch) of the test pins CPN protruding from the inner surfaces of the first body part BD1 may decrease as the number of times pressure is applied increases. Thus, the positions of the test pins CPN may change and the test pins CPN may not be in contact with the protrusion pins TPN.

However, when each of the test pins CPN has the third width W3 greater than the first width W1 according to embodiments, pressure may be dispersed in a large area. As can be seen through the second graph L2, the protrusion amount (ch) of the test pins CPN buckled on the inner surfaces of the first body part BD1 may decrease rapidly. Thus, the positions of the test pins CPN may not change, and the test pins CPN and the protrusion pins PTN may be in contact with each other. Therefore, the reliability of sensing incorrect fastening between the connection part CP and the first connector CNT1 may be improved.

The connection between the test pin CPN and the protrusion pin PTN has been explained in FIG. 7, but as it is illustrated in FIG. 8, the protrusion pins PTN and the power pins PPN, and the protrusion pins PTN and the signal pins SPN may also be in contact with each other in the same manner. Thus, the connection part CP may be electrically connected to the first printed circuit board PCB1.

Referring back to FIG. 3, the second printed circuit board PCB2 may include a second substrate SUB2, a second connector CNT2, and a power generating part PW. The major surface of the second substrate SUB2 may be parallel to a plane defined by the first direction DR1 and the second direction DR2. The second substrate SUB2 may extend longer in the first direction DR1 than in the second direction DR2.

The second connector CNT2 may be disposed adjacent to one side of two sides of the second substrate SUB2 opposed to each other in the second direction DR2, the one side facing the first printed circuit board PCB1. The second connector CNT2 may be electrically connected to the power generating part PW. The second connector CNT2 may have a structure substantially the same as that of the first connector CNT1. Hereinafter, description of the second connector CNT2 will be omitted.

The second connector CNT2 may be connected to one of the second body parts BD2 among the second body parts BD2. The connection part CP may electrically connect the first printed circuit board PCB1 and the second printed circuit board PCB2 with each other. The second printed circuit board PCB2 may be electrically connected to the display panel DP connected to the first printed circuit board PCB1.

The connection between the first connector CNT1 and the second body part BD2 has been described above, and may be similarly applied to the connection between the second connector CNT2 and the second body part BD2. The connection part CP may transfer, to the display panel DP, the electrical signal transferred from the second printed circuit board PCB2.

The power generating part PW may provide the display panel DP with power and/or common power. The power and/or the common power provided from the power generating part PW may be transferred to the display panel DP through the connection part CP.

Although not illustrated, the second connector CNT2 may further include an overcurrent protection part. When the second body part BD2 is incorrectly fastened to the first connector CNT1, the overcurrent protection part may receive a current provided from the test pins CPN and compare the current with a set current. If the current provided from the test pins CPN is abnormal, the overcurrent protection part may cut off the power. If the second body part BD2 and the first connector CNT1 are fastened normally, the power generating part PW may provide power to the display panel DP. Thus, during inspection of the electronic device ED (see FIG. 1), the overcurrent protection part may easily determine incorrect fastening.

According to an embodiment of the invention, a rigidity of test pins may be increased since the test pins are wider than signal pins. Thus, when the connection cable and the test pins are connected, the test pins may not be buckled and the position of the test pins may not change even when pressure is applied. Therefore, a defective connection between the connection cable and the test pins may be prevented, and the reliability of sensing incorrect fastening of the electronic device may be improved.

In the above, description has been made with reference to embodiments, but those skilled in the art or those of ordinary skill in the relevant technical field may understand that various modifications and changes may be made to the invention within the scope not departing from the spirit and the technology scope of the invention described in the claims to be described later. In addition, embodiments disclosed in the invention are not intended to limit the technical spirit of the invention, and all technical ideas within the scope of the following claims and their equivalents should be construed as being included in the scope of the invention.

What is claimed is:

1. An electronic device comprising:
a display panel of which a major surface is parallel to a plane defined by a first direction and a second direction crossing the first direction;
a first printed circuit board arranged in the second direction with the display panel, and electrically connected to the display panel;
a second printed circuit board disposed adjacent to a first side of the first printed circuit board opposed to a second side of the first printed circuit board adjacent to the display panel in the second direction; and
a connection part including a connection cable configured to connect the first printed circuit board and the second printed circuit board,
wherein the first printed circuit board includes
a first substrate, and
a plurality of terminals disposed on the first substrate to be electrically connected to the connection part and the display panel, and including signal pins, power pins, and test pins arranged in the first direction, and
a width of the test pin in the first direction is greater than a width of the signal pin in the first direction, and smaller than a width of the power pin in the first direction.

2. The electronic device of claim 1, wherein the power pins are disposed between the test pins spaced apart from each other in the first direction, and the signal pins are disposed between the power pins spaced apart from each other in the first direction.

3. The electronic device of claim 1, further comprising:
a flexible circuit board disposed between the display panel and the first printed circuit board; and
a data driving chip mounted on the flexible circuit board,
wherein the data driving chip is electrically connected to the display panel and the first printed circuit board.

4. The electronic device of claim 3, wherein the first printed circuit board comprises a plurality of printed wirings configured to connect the flexible circuit board and the terminals.

5. The electronic device of claim 1, wherein when the test pins are all connected to the connection cable, the second printed circuit board transmits a signal to the display panel.

6. The electronic device of claim 1, wherein the first printed circuit board further comprises a first connector disposed on the first side, and
the terminals are disposed inside a fastening groove defined in the first connector.

7. The electronic device of claim 6, wherein the first connector comprises:
a first body part defining the fastening groove therein; and
a cover part disposed on the first body part and covering the terminals in a plan view.

8. The electronic device of claim 6, wherein the connection part further comprises:
a plurality of second body parts connected to both two ends of the connection cable in the second direction; and
a plurality of protrusion pins disposed on a side of the second body parts facing the first connector,
the protrusion pins are electrically connected to the connection cable and in contact with the terminals.

9. The electronic device of claim 8, wherein an upper surface of each of the terminals comprises:
a second part, which is a highest part of the upper surface; and
a first part, which is a remaining part of the upper surface and of which height is lower than a height of the second part,
wherein a corresponding protrusion pin of the plurality of protrusion pins is in contact with the first part.

10. The electronic device of claim 8, wherein the second printed circuit board comprises:
a second substrate; and
a second connector connected to the connection part and disposed on a side the second substrate adjacent to the first printed circuit board.

11. The electronic device of claim 10, wherein one of the second body parts is connected to the first connector, and another one of the second body parts is connected to the second connector.

12. An electronic device comprising:
a display panel including a plurality of pixels, which display an image;
a first printed circuit board adjacent to one side of the display panel, and including a plurality of terminals arranged in a first direction and electrically connected to the display panel;
a second printed circuit board adjacent to a first side of the first printed circuit board opposed to a second side of the first printed circuit board adjacent to the display panel in a second direction crossing the first direction; and
a connection part including a connection cable configured to connect the first printed circuit board and the second printed circuit board,
wherein the terminals include a plurality of signal pins, a plurality of power pins, and a plurality of test pins, and
a width of the signal pins in the first direction, a width of the power pins in the first direction, and a width of the test pins in the first direction are different from each other.

13. The electronic device of claim 12, wherein the width of the test pins in the first direction is greater than the width of the signal pins in the first direction, and smaller than the width of the power pins in the first direction.

14. The electronic device of claim 12, wherein the connection cable is electrically connected to the signal pins, the power pins, and the test pins.

15. The electronic device of claim 12, further comprising a flexible circuit board disposed between the display panel and the first printed circuit board,
wherein the flexible circuit board is electrically connected to the terminals.

16. The electronic device of claim 15, wherein the first printed circuit board further comprises printed wirings electrically connected to the terminals and the flexible circuit board.

17. The electronic device of claim 12, wherein the first printed circuit board further comprises:
a first substrate disposed between the display panel and the second printed circuit board; and
a first connector disposed on the first side, and defining a fastening groove therein,
wherein the connection cable is connected to the terminals, which are disposed inside the fastening groove.

18. The electronic device of claim 17, wherein the second printed circuit board comprises:
a second substrate; and
a second connector disposed on one side of the second substrate adjacent to the first printed circuit board,
wherein the connection cable is connected to the second connector.

19. The electronic device of claim 12, wherein the power pins are disposed between the test pins spaced apart from each other in the first direction, and the signal pins are disposed between the power pins spaced apart from each other in the first direction.

20. The electronic device of claim 12, wherein when the test pins are all connected to the connection cable, the second printed circuit board provides a signal to the display panel.
